(19) United States
(12) Patent Application Publication
(10) Pub. No.: US 2025/0241005 A1
(43) Pub. Date: Jul. 24, 2025

(54) ISOLATION STRUCTURES AND METHODS OF FORMING THE SAME

(71) Applicant: Taiwan Semiconductor Manufacturing Company Ltd., Hsinchu (TW)

(72) Inventors: Chung-Huai CHANG, Taichung City (TW); Wen-Hao CHEN, Taichung City (TW); Chien-Yuan CHEN, Taichung City (TW); Hsueh-Liang CHOU, Jhubei City (TW)

(21) Appl. No.: 18/417,646

(22) Filed: Jan. 19, 2024

(51) Int. Cl. H01L 29/78; H01L 21/308; H01L 21/311; H01L 21/762; H01L 29/66

(52) U.S. Cl. CPC H10D 30/65; H01L 21/3083; H01L 21/31111; H01L 21/76224; H10D 30/0281

(57) ABSTRACT

Using a same hardmask layer during formation of some isolation structures (e.g., shallower shallow trench isolation structures) and during formation of additional isolation structures (e.g., shallow trench isolation structures) results in the isolation structures being approximately level with a horizontal surface of a substrate in which the isolation structures are formed. That is, a step height of the isolation structures is reduced. Therefore, heights of portions of gates that extend over the isolation structures are increased. The increased heights of the gates result in increased landing areas for contacts, which helps prevent current leakage and thus improves performance of electronic devices that include the isolation structures.

### BACKGROUND

Power metal-oxide-semiconductor field-effect transistors (MOSFETs) are MOSFETs designed to handle significant power levels, such as high voltages and/or high currents. Power MOSFETs may be used in display drivers, power converters, motor controllers, and vehicle power devices, among other examples. One type of power MOSFET is a laterally diffused metal-oxide-semiconductor (LDMOS) transistor. LDMOS transistors exhibit high gain, high power output, and high efficiency at high frequencies, such that LDMOS transistors are often used with microwave and radio frequency power amplifiers.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIG. 2 is a diagram of an example semiconductor structure described herein.

FIGS. 3A-3B are diagrams of example semiconductor structures described herein.

FIG. 4 is a diagram of an example semiconductor structure described herein.

FIGS. 5A-5I are diagrams of an example implementation described herein.

FIG. 6 is a diagram of example components of one or more devices of FIG. 1 described herein.

FIG. 7 is a flowchart of an example process associated with forming semiconductor structures described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some electronic devices, laterally diffused metal-oxide-semiconductor (LDMOS) field effect transistors (FETs) may be used. A shallow trench isolation (STI) structure may isolate different transistors in LDMOS devices. Additionally, in some LDMOS devices, a dielectric (e.g., silicon oxide) may be inserted at a drift region of an oxide definition (OD) surface to sustain a higher breakdown voltage. This process forms shallower STI (SSTI) structures. Gates of the LDMOS transistors may be formed that extend over OD regions that are defined by the isolation structures.

The STI structures may extend beyond a horizontal surface of a substrate in which the STI structures are formed. This extension may be referred to as a “step height.” The step height of the STI structures is even larger when the SSTI structures are incorporated into an STI process. The step height of the STI structures reduces heights of the gates at portions of the gates that extend over the OD regions. The reduced heights of the gates result in reduced landing areas for contacts, which may result in current leakage and thus reduced performance of the LDMOS devices.

Some implementations described herein provide techniques and apparatuses for depositing additional hardmask material during formation of isolation structures (e.g., SSTI structures), which enables reuse of the same hardmask material during formation of additional isolation structures (e.g., STI structures). As a result, the STI structures are approximately level with a horizontal surface of a substrate in which the STI structures are formed. That is, a step height of the STI structures is reduced. Therefore, heights of portions of gates that extend over the STI structures are increased. The increased heights of the gates result in increased landing areas for contacts, which helps prevent current leakage and thus improves performance of electronic devices (e.g., LDMOS devices) that include the STI structures.

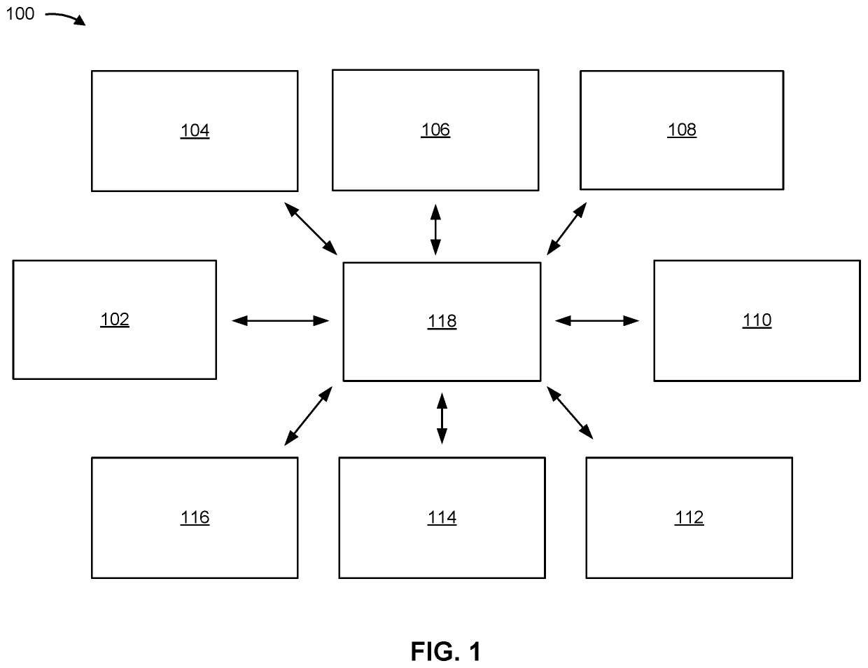

FIG. 1 is a diagram of an example environment 100 in which systems and/or methods described herein may be implemented. As shown in FIG. 1, environment 100 may include a plurality of semiconductor processing tools 102-116 and a wafer/die transport tool 118. The plurality of semiconductor processing tools 102-116 may include a deposition tool 102, an exposure tool 104, a developer tool 106, an etch tool 108, a planarization tool 110, a plating tool 112, a photoresist removal tool 114, a cleaning tool 116, and/or another semiconductor processing tool. The tools included in the example environment 100 may be included in a semiconductor clean room, a semiconductor foundry, a semiconductor processing and/or manufacturing facility, or another location.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma-enhanced CVD (PECVD) tool, a low pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, an epitaxy tool, or another type of CVD tool. In some implementations, the deposition tool 102 includes a physical vapor deposition (PVD) tool, such as a sputtering tool or another type of PVD tool. In some implementations, the example environment 100 includes a plurality of types of deposition tools 102.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical polishing (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device flat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The photoresist removal tool 114 is a semiconductor processing tool that is capable of removing remaining portions of a photoresist layer from a substrate after the etch tool 108 removes portions of the substrate. For example, the photoresist removal tool 114 may use a chemical stripper and/or another technique to remove a photoresist layer from a substrate.

The cleaning tool 116 is a semiconductor processing tool that is capable of cleaning a substrate, wafer, or semiconductor device. For example, the etch tool 108 may include a wet cleaning tool (e.g., using water), a dry cleaning tool (e.g., using plasma), and/or the like. In some implementations, the cleaning tool 116 includes a chamber that is filled with a cleaning material, and the substrate is placed in the chamber for a particular time period to clean the substrate (e.g., remove organic materials and/or removed oxidized molecules, among other examples). In some implementations, the cleaning tool 116 may use an ionized gas to isotropically or directionally clean the substrate.

The wafer/die transport tool 118 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 118 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

In some implementations, one or more of the semiconductor processing tools 102-116 and/or the wafer/die transport tool 118 may perform one or more semiconductor processing operations described herein. For example, one or more of the semiconductor processing tools 102-116 and/or the wafer/die transport tool 118 may form a hardmask layer over a substrate; form, using the hardmask layer, one or more SSTI structures in the substrate; form, using the hardmask layer, an STI structure in the substrate; perform CMP on the STI structure; remove the hardmask layer; and/or form at least one gate over an OD region formed by the SSTI structures.

The number and arrangement of tools shown in FIG. 1 are provided as one or more examples. In practice, there may be additional tools, fewer tools, different tools, or differently arranged tools than those shown in FIG. 1. Furthermore, two or more tools shown in FIG. 1 may be implemented within a single tool, or a single tool shown in FIG. 1 may be implemented as multiple, distributed tools. Additionally, or alternatively, a set of tools (e.g., one or more tools) of environment 100 may perform one or more functions described as being performed by another set of tools of environment 100.

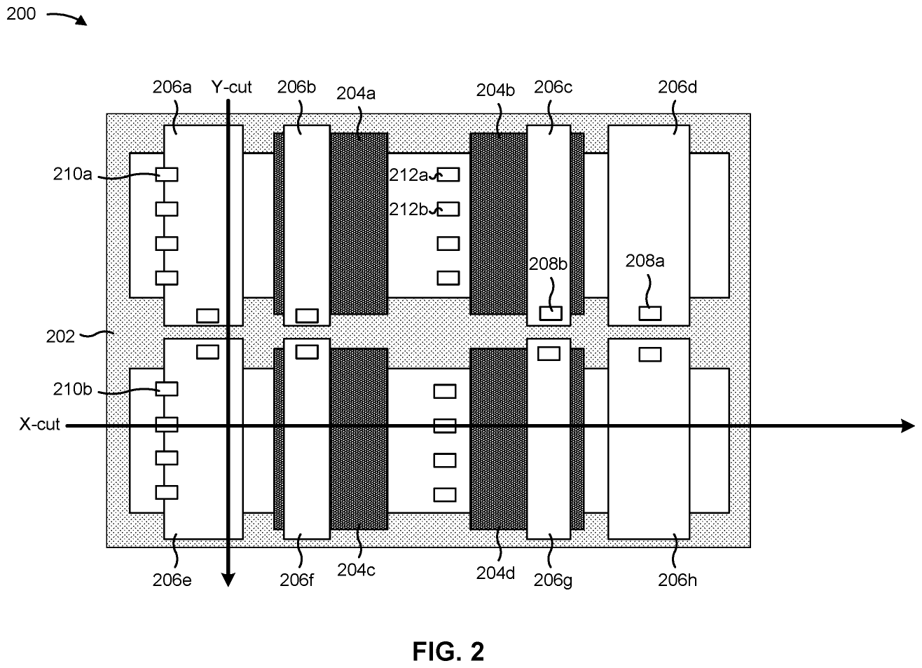

FIG. 2 is a diagram of a top view of a cross-section of an example semiconductor device 200 described herein. The semiconductor device 200 includes an example of a semiconductor device, such as a display driver, a power converter, a motor controller, a vehicle power device, or another type of semiconductor device that includes an LDMOS.

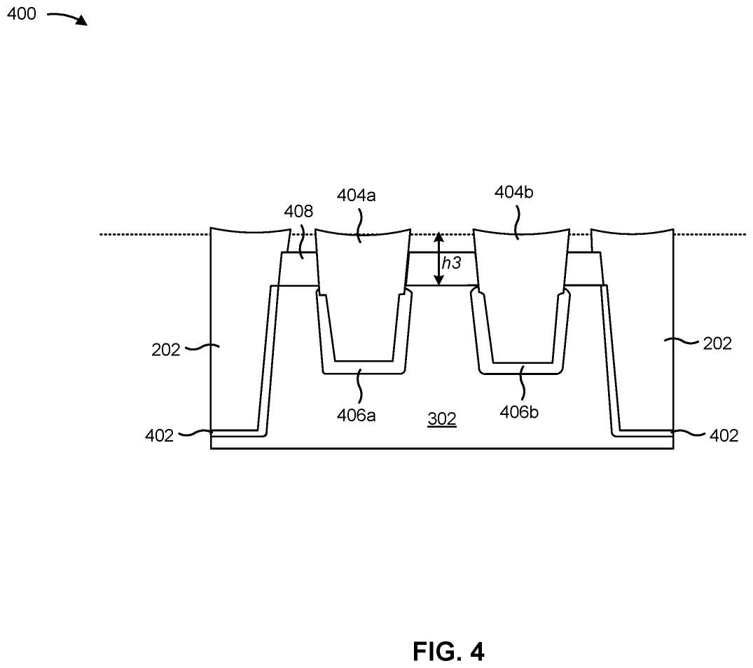

As shown in FIG. 2, the example semiconductor device 200 may include an isolation structure, such as an STI structure 202. The STI structure 202 may electrically isolate different transistors within the example semiconductor device 200. As described in connection with FIG. 4, the STI structure 202 may include a lining layer (e.g., e.g., an antireflective coating (ARC), such as a nitrogen-containing material, and/or a passivation layer, among other examples) and a dielectric filling (e.g., an oxide material). Additionally, the example semiconductor device 200 may include additional isolation structures, such as SSTI structures 204a, 204b, 204c, and 204d that form an OD region. The SSTI structures 204a, 204b, 204c, and 204d may similarly include a lining layer and a dielectric filling, as described in connection with FIG. 4. The SSTI structures 204a, 204b, 204c, and 204d have smaller depths than the STI structure 202. That is, the STI structure 202 extends further into a substrate (not shown in FIG. 2) than the SSTI structures 204a, 204b, 204c, and 204d.

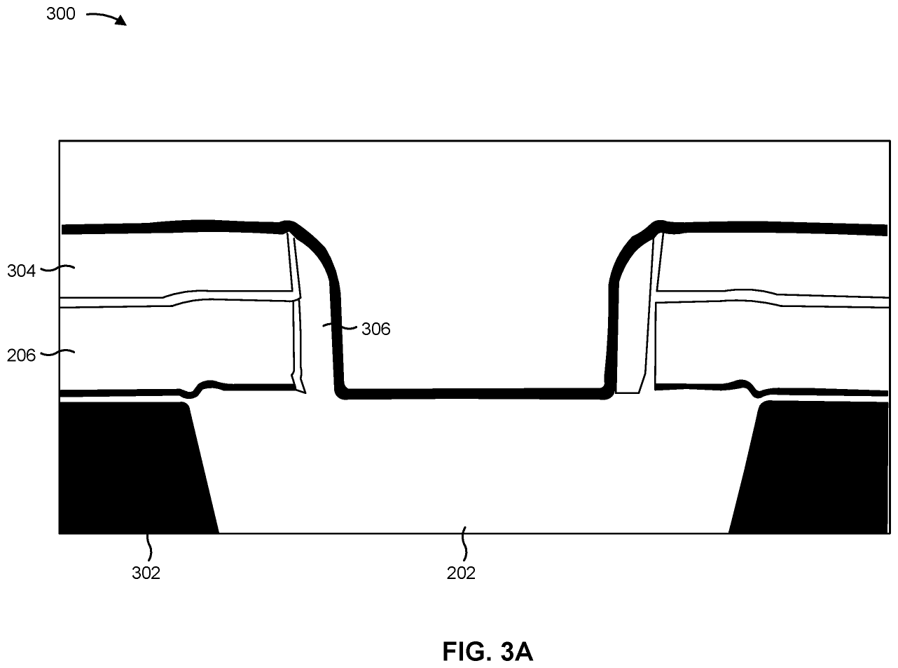

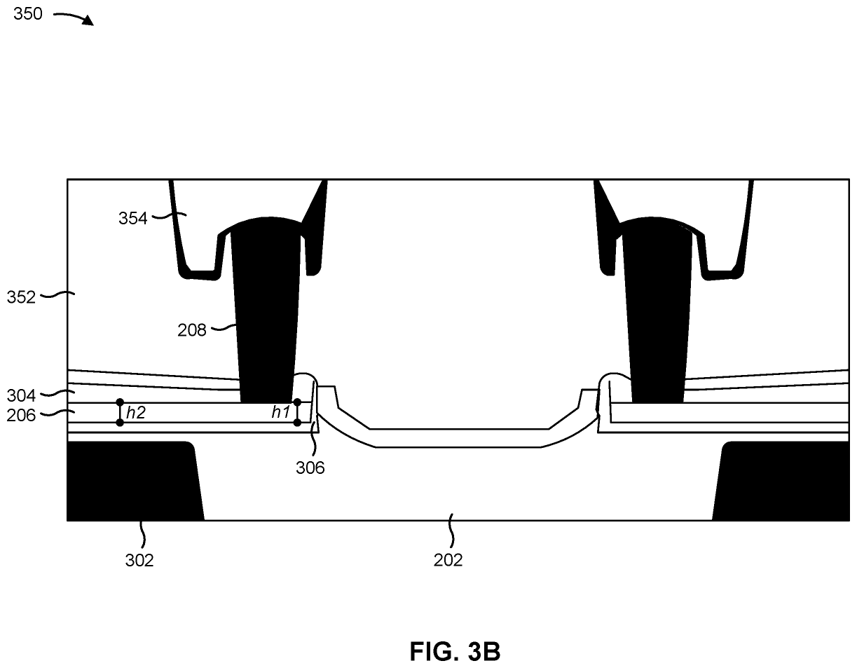

The example semiconductor device 200 further includes a plurality of gates 206. The example semiconductor device 200 includes four gates formed adjacent to the SSTI structures (shown as gates 206a, 206d, 206c, and 206h) as well as four gates formed over the SSTI structures (shown as gates 206b, 206c, 206f, and 206g). As described in connection with FIGS. 3A-3B, each gate 206 may include a crystalline layer and a spacer around a perimeter of the gate. Additionally, each gate 206 may be in physical contact with a metal plug 208 (e.g., plugs 208a and 208b in FIG. 2). Accordingly, the gates 206 may control a flow of current between source regions and drain regions of the example semiconductor device 200. For example, the gate 206c may be energized (e.g., by applying a voltage or a current to the metal plug 208b) to cause a conductive channel to form between a source region and a drain region connected by the gate 206c. The conductive channel may be removed or closed by de-energizing the gate 206c, which blocks and/or prevents the flow of photocurrent between the source region and the drain region that are connected by the gate 206c.

As further shown in FIG. 2, source regions of the example semiconductor device 200 may be in physical contact with source contacts 210 (e.g., metal plugs 210a and 210b in FIG. 2). Similarly, drain regions of the example semiconductor device 200 may be in physical contact with drain contacts 212 (e.g., metal plugs 212a and 212b in FIG. 2).

As indicated above, FIG. 2 is provided as an example. Other examples may differ from what is described with regard to FIG. 2. Other examples may include additional gates or fewer gates, as compared with the example semiconductor device 200 shown in FIG. 2. Similarly, other examples may include additional source contacts or fewer source contacts, as compared with the example semiconductor device 200 shown in FIG. 2, and/or additional drain contacts or fewer drain contacts, as compared with the example semiconductor device 200 shown in FIG. 2.

FIG. 3A is a diagram of a cross-section 300 along a Y-cut, as shown in FIG. 2, of an example semiconductor device. In FIG. 3A, gates of an LDMOS device have not undergone CMP. Additionally, gate contacts of the LDMOS device have not been formed.

As shown in FIG. 3A, an STI structure 202 is formed in a substrate 302. The substrate 302 may include a semiconductor die substrate, a semiconductor wafer, a stacked semiconductor wafer, or another type of substrate in which semiconductor pixels may be formed. For example, the substrate 302 may be formed of silicon (Si) (e.g., a silicon substrate), a material including silicon, a III-V compound semiconductor material such as gallium arsenide (GaAs), a silicon on insulator (SOI), or another type of semiconductor material. In some implementations, the substrate 302 is formed of a doped material (e.g., a p-doped material or an n-doped material) such as a doped silicon.

As further shown in FIG. 3A, a gate 206 may be formed at least partially over the STI structure 202. The gate 206 may be include a metal and/or a crystalline material. Because the STI structure 202 has a step height less than 2 nanometers (nm), as described in connection with FIG. 4, the gate 206 has a relatively uniform height over both the STI structure 202 and the substrate 302, as described in greater detail in connection with FIG. 3B.

As further shown in FIG. 3A, a passivation layer 304 may be formed over the gate 206. For example, the passivation layer 304 may protect portions of the gate 206 during formation of a gate contact, as described in connection with FIG. 3B. Additionally, a spacer 306 (e.g., a sidewall spacer) may be formed around a perimeter of the gate 206. The spacer 306 may include a silicon oxide (SiOₓ), a silicon nitride (SiₓN_{y}), a silicon oxy carbide (SiOC), and/or a silicon oxycarbonitride (SiOCN), among other examples. The spacer 306 may similarly protect portions of the gate 206 during formation of a gate contact, as described in connection with FIG. 3B.

FIG. 3B is a diagram of a cross-section 350 along the Y-cut of the example semiconductor device shown in FIG. 3A. In FIG. 3B, gates of the LDMOS device have undergone CMP, and gate contacts of the LDMOS device have been formed.

As shown in FIG. 3B, a dielectric layer 352 has been formed over the passivation layer 304, the gate 206, and the substrate 302 (as well as the STI structure 202). Additionally, a gate contact 208 has been formed in the dielectric layer 352. The gate contact 208 may be an interconnector and/or a metal plug (e.g., as described in connection with FIG. 2) and may include tungsten (W), cobalt (Co), ruthenium (Ru), titanium (Ti), aluminum (Al), copper (Cu), and/or gold (Au), among other examples of conductive materials. The gate contact 208 may be in physical contact with the gate 206 (e.g., through the passivation layer 304), which allows the gate contact 208 to conduct voltage to the gate 206 and energize the gate 206. The gate contact 208 may also be in physical contact with a metal plug 354 that further connects the gate 206 to an interconnect region (e.g., that connects the semiconductor device to a package).

As further shown in FIG. 3B, the gate 206 has a first height (e.g., represented by h1) over the STI structure and a second height (e.g., represented by h2) over the substrate 302. The gate 206 also has the second height h2 over an OD region formed by an SSTI structure (not shown in FIG. 3B). The first height h1 and the second height h2 are approximately equal. As used herein, “approximately equal” refers to being equal within a margin of error (e.g., a margin of error of 5% or less). Accordingly, a difference between the first height h1 and the second height h2 satisfies a threshold with a value corresponding to the margin of error.

Because a step height of the STI structure 202 is less than 2 nm, the gate 206 exhibits an increased height over the STI structure 202. As a result, the first height h1 and the second height h2 are approximately equal, which results in an increased landing area for the gate contact 208. The increased landing area helps prevent current leakage and thus improves performance of the example semiconductor device.

As indicated above, FIGS. 3A-3B are provided as an example. Other examples may differ from what is described with regard to FIGS. 3A-3B. For example, the spacer 306 may be omitted from the example semiconductor device.

FIG. 4 is a diagram of a cross-section 400 along an X-cut, as shown in FIG. 2, of an example semiconductor device. In FIG. 4, isolation structures of an LDMOS device have been formed but gates of the LDMOS device are not yet formed.

As shown in FIG. 4, a substrate 302 of the example semiconductor device includes an STI structure 202 as well as SSTI structures 404a and 404b. The SSTI structures 404a and 404b are similar to the STI structure 202 but do not extend as far into the substrate 302 as the STI structure 202. Accordingly, in some implementations, the STI structure 202 may have a higher aspect ratio than the SSTI structures 404a and 404b, as shown in FIG. 4.

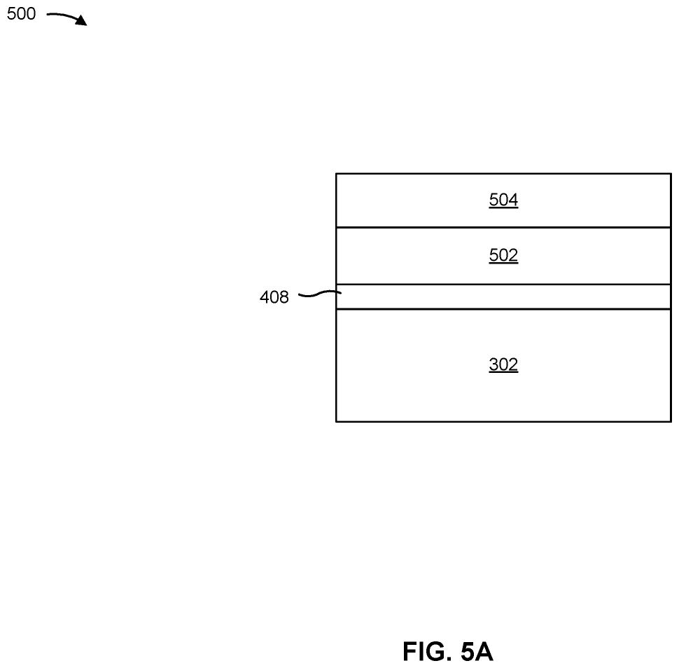

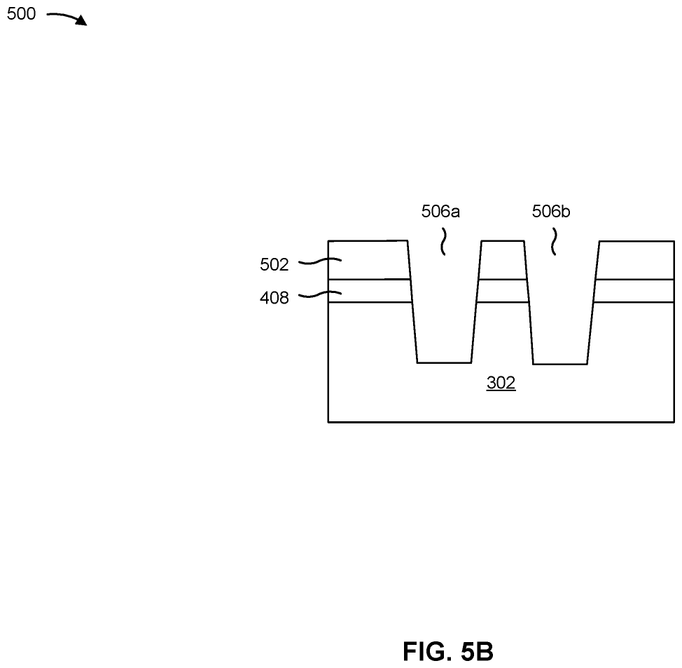

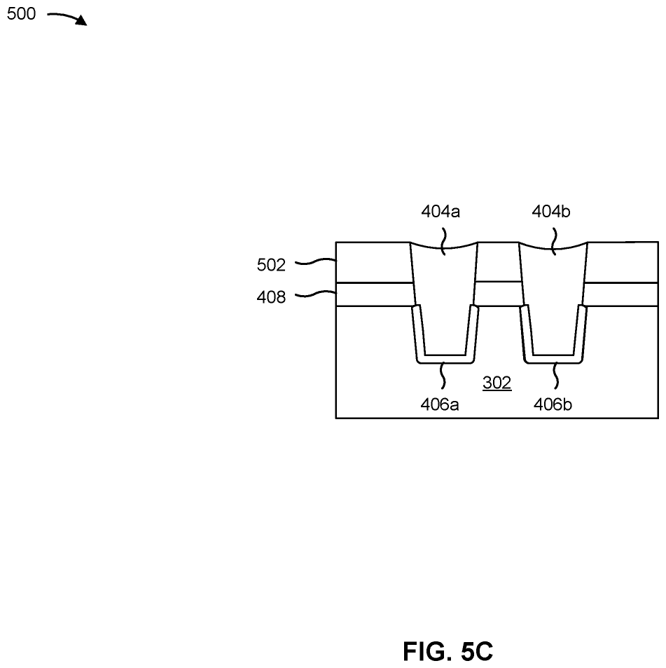

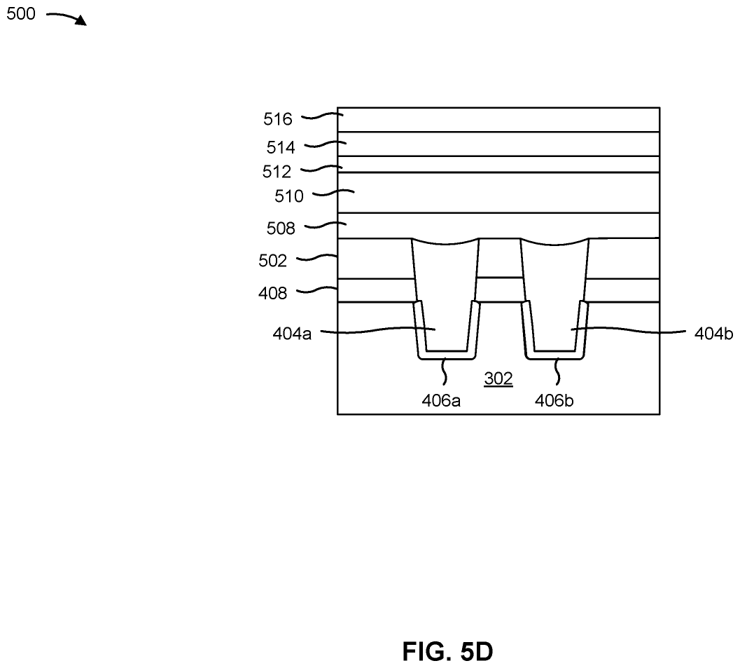

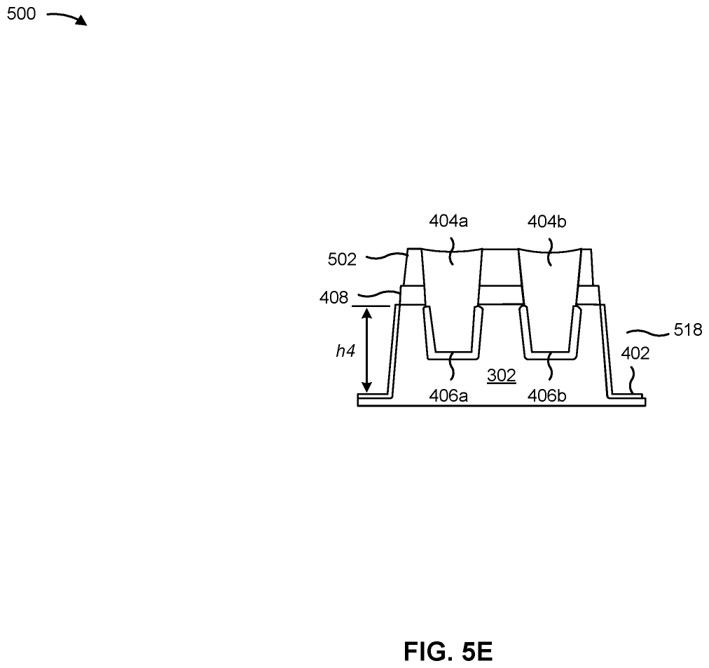

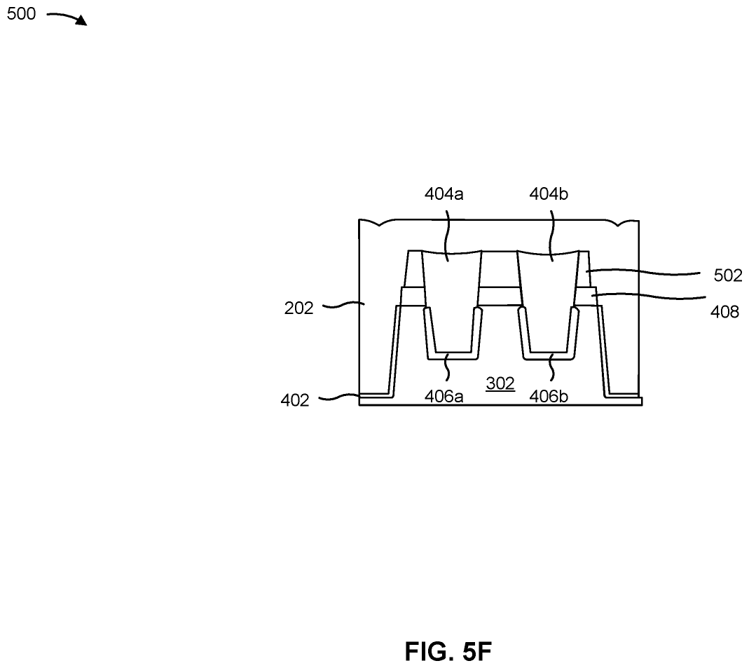

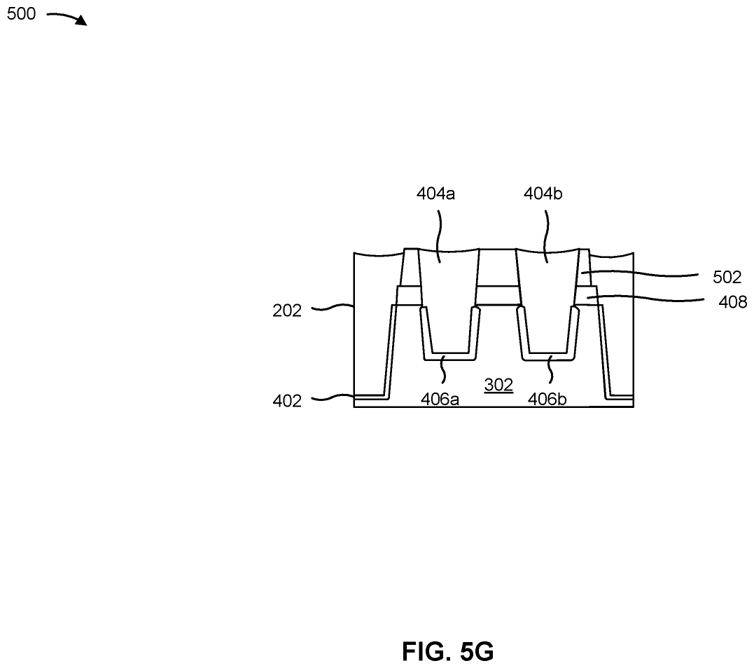

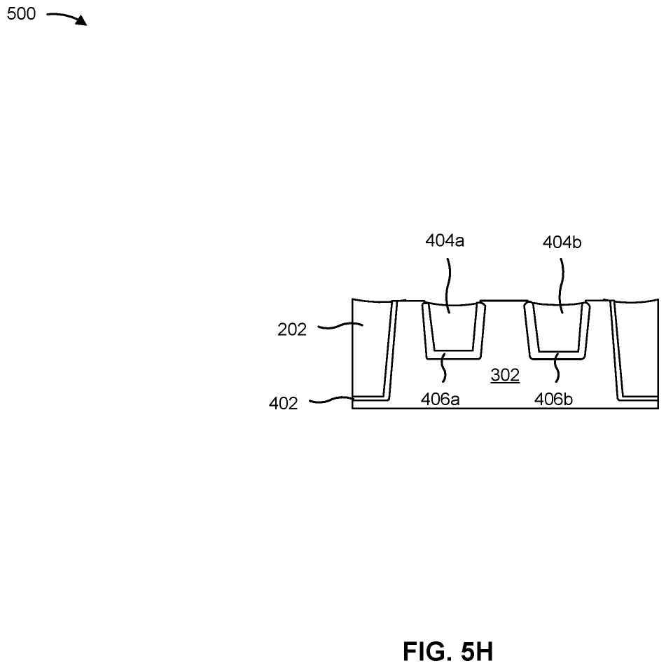

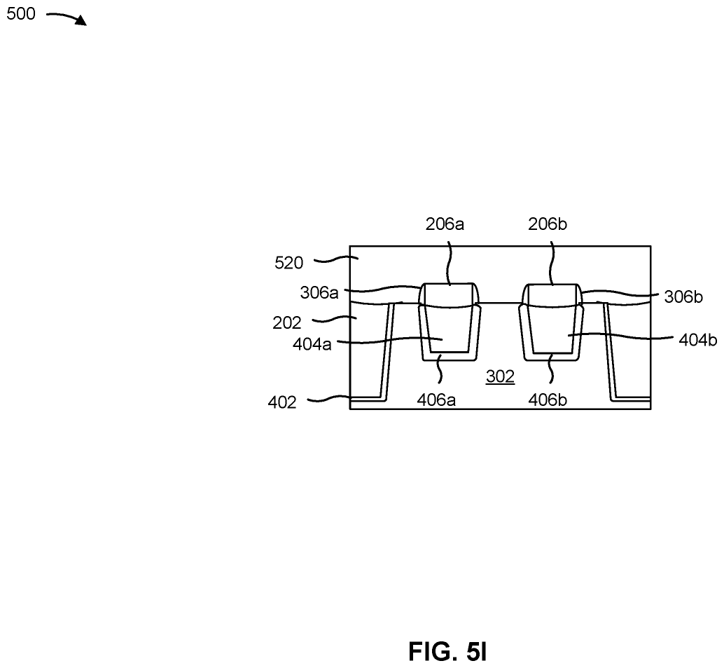

As further shown in FIG. 4, the STI structure 202 includes a lining layer 402. Additionally, the SSTI structures 404a and 404b include lining layers 406a and 406b, respectively. In FIG. 4, padding layer 408 has not yet been removed; therefore, a step height of the STI structure 202 and the SSTI structures 404a and 404b (e.g., represented by h3) is measured through the padding layer 408 (that is, from a top surface of the substrate 302). The step height thus represents how far the STI structure 202 and the SSTI structures 404a and 404b extend above (or extend out of) the substrate 302. The step height h3 is in a range from 0.0 nm to approximately 2.0 nm. Forming the STI structure 202 and the SSTI structures 404a and 404b with a step height no larger than 2.0 nm prevents the step height from reducing a height of a gate formed over the STI structure 202 and/or the SSTI structures 404a and 404b (e.g., as described in connection with FIG. 5I). A larger step height would reduce the height of the gate, which in turn would result in reduced landing areas for a gate contact and in current leakage and reduced performance of the example semiconductor device.

Additionally, a step height of the STI structure 202 and a step height of the SSTI structures 404a and 404b is approximately equal (that is, both represented by h3 in FIG. 4). Forming the STI structure 202 and the SSTI structures 404a and 404b with a same hardmask layer (e.g., as described in connection with FIGS. 5A-5F) results in approximately equal step heights. Different hardmask layers would result in different step heights and generally would result in a step height of more than 2.0 nm for the STI structure 202.

As indicated above, FIG. 4 is provided as an example. Other examples may differ from what is described with regard to FIG. 4. Other examples may include additional SSTI structures, as compared with the example semiconductor structure shown in FIG. 4. Additionally, or alternatively, other examples may omit the lining layer 402 and/or the lining layers 406a and 406b.

FIGS. 5A-5I are diagrams of an example implementation 500 described herein. Example implementation 500 may be an example process for forming an example semiconductor device 200 described herein. The example semiconductor device 200 may include a display driver, a power converter, a motor controller, a vehicle power device, or another type of semiconductor device that includes an LDMOS.

As shown in FIG. 5A, the example process for forming the semiconductor device may be performed in connection with a substrate 302. The substrate 302 may include a semiconductor die substrate, a semiconductor wafer, a stacked semiconductor wafer, or another type of substrate in which semiconductor pixels may be formed. In some implementations, the substrate 302 is formed of a doped material (e.g., a p-doped material or an n-doped material) such as a doped silicon.

As further shown in FIG. 5A, the example process may be performed in connection with a padding layer 408. For example, a deposition tool 102 may form the padding layer 408 over and/or on a frontside surface of the substrate 302. In some implementations, a deposition tool 102 forms the padding layer 408 using a spin-coating technique, a CVD technique, a PVD technique, an ALD technique, and/or another deposition technique. The padding layer 408 may include an oxide material and/or another type of material that protects the substrate 302 during subsequent processes.

As further shown in FIG. 5A, the example process may be performed in connection with a hardmask layer 502. For example, a deposition tool 102 may form the hardmask layer 502 over and/or on a frontside surface of the substrate 302 and the padding layer 408. In some implementations, a deposition tool 102 forms the hardmask layer 502 using a spin-coating technique, a CVD technique, a PVD technique, an ALD technique, and/or another deposition technique. The hardmask layer 502 may include a silicon nitride (SiN) and/or another type of masking layer. The hardmask layer 502 may have a height in a range from approximately 500 Ångströms (Å) to approximately 1000 Å. Selecting a height of no more than 1000 Å ensures that the hardmask layer 502 may be removed (e.g., as described in connection with FIG. 5H) without an extended etch process. An extended etch process would damage isolation structures formed using the hardmask layer 502. Selecting a height of at least 500 Å ensures that the hardmask layer 502 will remain present until the isolation structures are formed. The isolation structures would be damaged were the hardmask layer 502 to be inadvertently etched before the isolation structures were complete.

As further shown in FIG. 5A, the example process may be performed in connection with a photoresist (PR) layer 504. For example, a deposition tool 102 may form the PR layer 504 over and/or on a frontside surface of the substrate 302, the padding layer 408, and the hardmask layer 502. In some implementations, a deposition tool 102 forms the PR layer 504 using a spin-coating technique, a CVD technique, a PVD technique, an ALD technique, and/or another deposition technique. The PR layer 504 may include a tetraethyl orthosilicate (TEOS) oxide and/or another type of photoresist material. The PR layer 504 may have a height in a range from approximately 400 Å to approximately 800 Å. Selecting a height of no more than 800 Å ensures that the PR layer 504 may be removed (e.g., as described in connection with FIG. 5B) without an extended etch process. An extended etch process would damage the substrate 302. Selecting a height of at least 400 Å ensures that the PR layer 504 is sufficiently large to pattern during etching of recesses into the substrate 302 (e.g., as described in connection with FIG. 5B). The substrate 302 would be damaged were the PR layer 504 to be incorrectly patterned.

As shown in FIG. 5B, recesses 506a and 506b may be formed in the substrate 302. In one example, the PR layer 504 may be patterned (e.g., by an exposure tool 104 exposing the PR layer 504 to a radiation source to form a pattern on the PR layer 504), portions of the PR layer 504 are etched to expose the pattern (e.g., by a developer tool 106 developing and removing the portions of the PR layer 504), and the recesses 506a and 506b are formed (e.g., by an etch tool 108 using a wet etch technique, a dry etch technique, a plasma-enhanced etch technique, and/or another type of etch technique). Additionally, as shown in FIG. 5B, the PR layer 504 may be removed. For example, a photoresist removal tool 114 may remove remaining portions of the PR layer 504 (e.g., using a chemical stripper, a plasma asher, and/or another technique) after the recesses 506a and 506b are formed.

As shown in FIG. 5C, lining layers 406a and 406b may be formed in the recesses 506a and 506b, respectively. For example, a deposition tool 102 may form the lining layers 406a and 406b using a conformal technique such that the lining layers 406a and 406b are formed only on exposed surfaces of the substrate 302 (and not on exposed surfaces of the padding layer 408 or the hardmask layer 502). In some implementations, a cleaning tool 116 may clean the recesses 506a and 506b (e.g., using a combination of acid, hydrogen peroxide, and deionized water, among other examples) before the lining layers 406a and 406b are formed.

As further shown in FIG. 5C, dielectric material may be formed in the recesses 506a and 506b to form SSTI structures 404a and 404b, respectively. In some implementations, a deposition tool 102 forms the SSTI structures 404a and 404b using a spin-coating technique, a CVD technique, a PVD technique, an ALD technique, and/or another deposition technique. Because the dielectric material may overfill the recesses 506a and 506b, a planarization tool 110 may perform CMP on the SSTI structures 404a and 404b to remove excess dielectric material. The CMP may also cause “dishing” of the SSTI structures 404a and 404b, as shown in FIG. 5C. In particular, top surfaces of the SSTI structures 404a and 404b may be uneven in that edges of the SSTI structures 404a and 404b are taller than middles of the SSTI structures 404a and 404b.

As shown in FIG. 5D, a plurality of layers may be formed over the hardmask layer 502 and the SSTI structures 404a and 404b. An additional padding layer 508 may be formed. For example, a deposition tool 102 may form the additional padding layer 508 over and/or on a frontside surface of the substrate 302, the padding layer 408, the hardmask layer 502, and the SSTI structures 404a and 404b.

An anti-reflection dielectric (ARD) layer 510 may also be formed. For example, a deposition tool 102 may form the ARD layer 510 over and/or on a frontside surface of the substrate 302, the padding layer 408, the hardmask layer 502, the SSTI structures 404a and 404b, and the additional padding layer 508. The ARD layer 510 may have a height in a range from approximately 500 Å to approximately 1400 Å. Selecting a height of no more than 1400 Å ensures that the ARD layer 510 may be removed (e.g., as described in connection with FIG. 5E) without an extended etch process. An extended etch process might damage the SSTI structures 404a and 404b. Selecting a height of at least 500 Å ensures that the ARD layer 510 is sufficiently large to prevent self-interference of light during patterning of a PR layer 516 (e.g., as described in connection with FIG. 5E). Self-interference of light can cause formation of an STI structure (e.g., as described in connection with FIG. 5F) in a wrong location in the substrate 302.

A middle anti-reflective layer 512 may also be formed. For example, a deposition tool 102 may form the middle anti-reflective layer 512 over and/or on a frontside surface of the substrate 302, the padding layer 408, the hardmask layer 502, the SSTI structures 404a and 404b, the additional padding layer 508, and the ARD layer 510. The middle anti-reflective layer 512 may be formed of silicon oxynitride (SiON) and/or another similar material. The middle anti-reflective layer 512 may have a height in a range from approximately 200 Å to approximately 300 Å. Selecting a height of no more than 300 Å ensures that the middle anti-reflective layer 512 may be removed (e.g., as described in connection with FIG. 5E) without an extended etch process. An extended etch process might damage the SSTI structures 404a and 404b. Selecting a height of at least 200 Å ensures that the middle anti-reflective layer 512 is sufficiently large to prevent self-interference of light during patterning of a PR layer 516 (e.g., as described in connection with FIG. 5E). Self-interference of light can cause formation of an STI structure (e.g., as described in connection with FIG. 5F) in a wrong location in the substrate 302.

An anti-reflective coating (ARC) 514 may also be formed. For example, a deposition tool 102 may form the ARC 514 over and/or on a frontside surface of the substrate 302, the padding layer 408, the hardmask layer 502, the SSTI structures 404a and 404b, the additional padding layer 508, the ARD layer 510, and the middle anti-reflective layer 512. The ARC 514 may have a height in a range from approximately 300 Å to approximately 600 Å. Selecting a height of no more than 600 Å ensures that the ARC 514 may be removed (e.g., as described in connection with FIG. 5E) without an extended etch process. An extended etch process might damage the SSTI structures 404a and 404b. Selecting a height of at least 300 Å ensures that the ARC 514 is sufficiently large to prevent self-interference of light during patterning of a PR layer 516 (e.g., as described in connection with FIG. 5E). Self-interference of light can cause formation of an STI structure (e.g., as described in connection with FIG. 5F) in a wrong location in the substrate 302.

A PR layer 516 may also be formed. For example, a deposition tool 102 may form the PR layer 516 over and/or on a frontside surface of the substrate 302, the padding layer 408, the hardmask layer 502, the SSTI structures 404a and 404b, the additional padding layer 508, the ARD layer 510, the middle anti-reflective layer 512, and the ARC 514. In some implementations, a deposition tool 102 forms the PR layer 516 using a spin-coating technique, a CVD technique, a PVD technique, an ALD technique, and/or another deposition technique. The PR layer 516 may have a height in a range from approximately 500 Å to approximately 1000 Å. Selecting a height of no more than 1000 Å ensures that the PR layer 516 may be removed (e.g., as described in connection with FIG. 5E) without an extended etch process. An extended etch process might damage the SSTI structures 404a and 404b. Selecting a height of at least 500 Å ensures that the PR layer 516 is sufficiently large to pattern during etching of a recess into the substrate 302 (e.g., as described in connection with FIG. 5E). The substrate 302 would be damaged were the PR layer 516 to be incorrectly patterned.

As shown in FIG. 5E, recess 518 may be formed in the substrate 302. In one example, the PR layer 516 may be patterned (e.g., by an exposure tool 104 exposing the PR layer 516 to a radiation source to form a pattern on the PR layer 516), portions of the PR layer 516 are etched to expose the pattern (e.g., by a developer tool 106 developing and removing the portions of the PR layer 516), and the recess 518 is formed (e.g., by an etch tool 108 using a wet etch technique, a dry etch technique, a plasma-enhanced etch technique, and/or another type of etch technique). The recess 518 may surround the SSTI structures 404a and 404b in the substrate 302 and thus is shown only partially in the cross-section view of FIG. 5E. Additionally, as shown in FIG. 5E, the PR layer 516 may be removed. For example, a photoresist removal tool 114 may remove remaining portions of the PR layer 516 (e.g., using a chemical stripper, a plasma asher, and/or another technique) after the recess 518 is formed. Additionally, as shown in FIG. 5E, the ARD layer 510, the middle anti-reflective layer 512, and the ARC 514 may be removed. The additional padding layer 508 may also be removed, and the hardmask layer 502 may be pulled back. As shown in FIG. 5E, a “pulled back” hardmask layer 502 results in the recess 518 being wider at the hardmask layer 502 than at the padding layer 408.

As shown in FIG. 5F, a lining layer 402 may be formed in the recess 518. For example, a deposition tool 102 may form the lining layer 402 using a conformal technique such that the lining layer 402 is formed only on exposed surfaces of the substrate 302 (and not on exposed surfaces of the padding layer 408, the hardmask layer 502, or the SSTI structures 404a and 404b). In some implementations, a cleaning tool 116 may clean the recess 518 (e.g., using a combination of acid, hydrogen peroxide, and deionized water, among other examples) before the lining layer 402 is formed.

As further shown in FIG. 5F, dielectric material may be formed in the recess 518 to form STI structure 202. In some implementations, a deposition tool 102 forms the STI structure 202 using a spin-coating technique, a CVD technique, a PVD technique, an ALD technique, and/or another deposition technique. As shown in FIG. 5F, the dielectric material may overfill the recess 518. Accordingly, as shown in FIG. 5G, a planarization tool 110 may perform CMP on the STI structure 202 to remove excess dielectric material. The CMP may also cause “dishing” of the STI structure 202, as shown in FIG. 5G. In particular, a top surface of the STI structure 202 may be uneven in that edges of the STI structure 202 are taller than a middle of the STI structure 202.

As shown in FIG. 5H, the hardmask layer 502 may be removed (e.g., using a hydrofluoric acid (HF) etch and/or another type of wet etch). Additionally, an OD region may be formed over the SSTI structures 404a and 404b (e.g., using ion implantation). As further shown in FIG. 5H, the padding layer 408 may be removed.

As shown in FIG. 5I, gates 206a and 206b may be formed over the SSTI structures 404a, and 404b, respectively. Although not shown in FIG. 5I, additional gates may be formed partially over the STI structures (e.g., as described in connection with FIGS. 2, 3A, and 3B). The gates 206a and 206b may be formed with spacers 306a and 306b, respectively. A dielectric layer 520 may be formed to cover the gates 206a and 206b (as well as exposed surfaces of the substrate 302, the SSTI structures 404a and 404b, and the STI structure 202). In some implementations, a deposition tool 102 forms the dielectric layer 520 using a spin-coating technique, a CVD technique, a PVD technique, an ALD technique, and/or another deposition technique.

As indicated above, FIGS. 5A-5I are provided as an example. Other examples may differ from what is described with regard to FIGS. 5A-5I. Other examples may include a bottom layer (BL) and a middle layer (ML) used in combination with the PR layer 504 and the hardmask layer 502. Additionally, or alternatively, other examples may omit the spacers 306a and 306b.

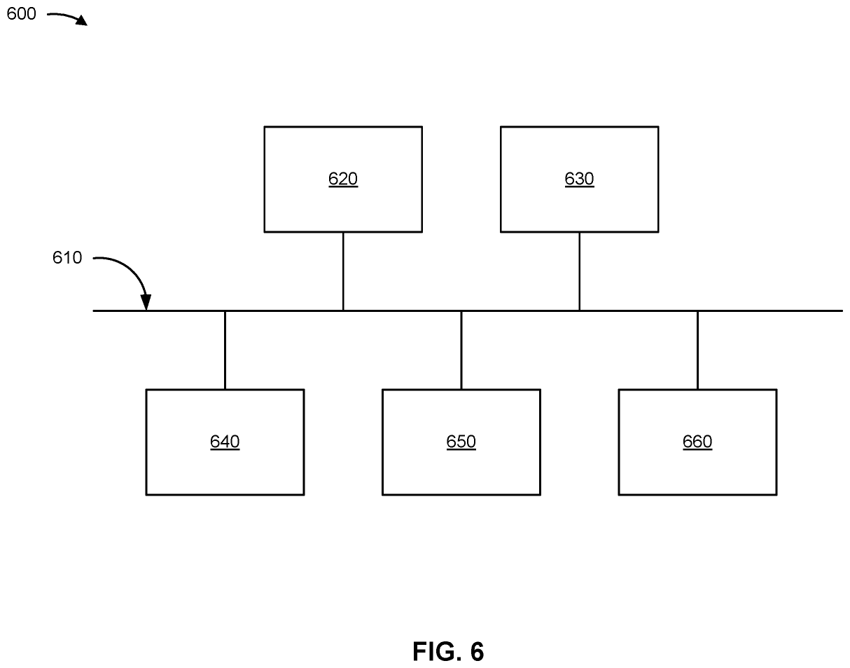

FIG. 6 is a diagram of example components of a device 600 described herein. In some implementations, one or more of the semiconductor processing tools 102-116 and/or the wafer/die transport tool 118 may include one or more devices 600 and/or one or more components of device 600. As shown in FIG. 6, device 600 may include a bus 610, a processor 620, a memory 630, an input component 640, an output component 650, and a communication component 660.

Bus 610 may include one or more components that enable wired and/or wireless communication among the components of device 600. Bus 610 may couple together two or more components of FIG. 6, such as via operative coupling, communicative coupling, electronic coupling, and/or electric coupling. Processor 620 may include a central processing unit, a graphics processing unit, a microprocessor, a controller, a microcontroller, a digital signal processor, a field-programmable gate array, an application-specific integrated circuit, and/or another type of processing component. Processor 620 is implemented in hardware, firmware, or a combination of hardware, firmware, and software. In some implementations, processor 620 may include one or more processors capable of being programmed to perform one or more operations or processes described elsewhere herein.

Memory 630 may include volatile and/or nonvolatile memory. For example, memory 630 may include random access memory (RAM), read only memory (ROM), a hard disk drive, and/or another type of memory (e.g., a flash memory, a magnetic memory, and/or an optical memory). Memory 630 may include internal memory (e.g., RAM, ROM, or a hard disk drive) and/or removable memory (e.g., removable via a universal serial bus connection). Memory 630 may be a non-transitory computer-readable medium. Memory 630 stores information, instructions, and/or software (e.g., one or more software applications) related to the operation of device 600. In some implementations, memory 630 may include one or more memories that are coupled to one or more processors (e.g., processor 620), such as via bus 610.

Input component 640 enables device 600 to receive input, such as user input and/or sensed input. For example, input component 640 may include a touch screen, a keyboard, a keypad, a mouse, a button, a microphone, a switch, a sensor, a global positioning system sensor, an accelerometer, a gyroscope, and/or an actuator. Output component 650 enables device 600 to provide output, such as via a display, a speaker, and/or a light-emitting diode. Communication component 660 enables device 600 to communicate with other devices via a wired connection and/or a wireless connection. For example, communication component 660 may include a receiver, a transmitter, a transceiver, a modem, a network interface card, and/or an antenna.

Device 600 may perform one or more operations or processes described herein. For example, a non-transitory computer-readable medium (e.g., memory 630) may store a set of instructions (e.g., one or more instructions or code) for execution by processor 620. Processor 620 may execute the set of instructions to perform one or more operations or processes described herein. In some implementations, execution of the set of instructions, by one or more processors 620, causes the one or more processors 620 and/or the device 600 to perform one or more operations or processes described herein. In some implementations, hardwired circuitry is used instead of or in combination with the instructions to perform one or more operations or processes described herein. Additionally, or alternatively, processor 620 may be configured to perform one or more operations or processes described herein. Thus, implementations described herein are not limited to any specific combination of hardware circuitry and software.

The number and arrangement of components shown in FIG. 6 are provided as an example. Device 600 may include additional components, fewer components, different components, or differently arranged components than those shown in FIG. 6. Additionally, or alternatively, a set of components (e.g., one or more components) of device 600 may perform one or more functions described as being performed by another set of components of device 600.

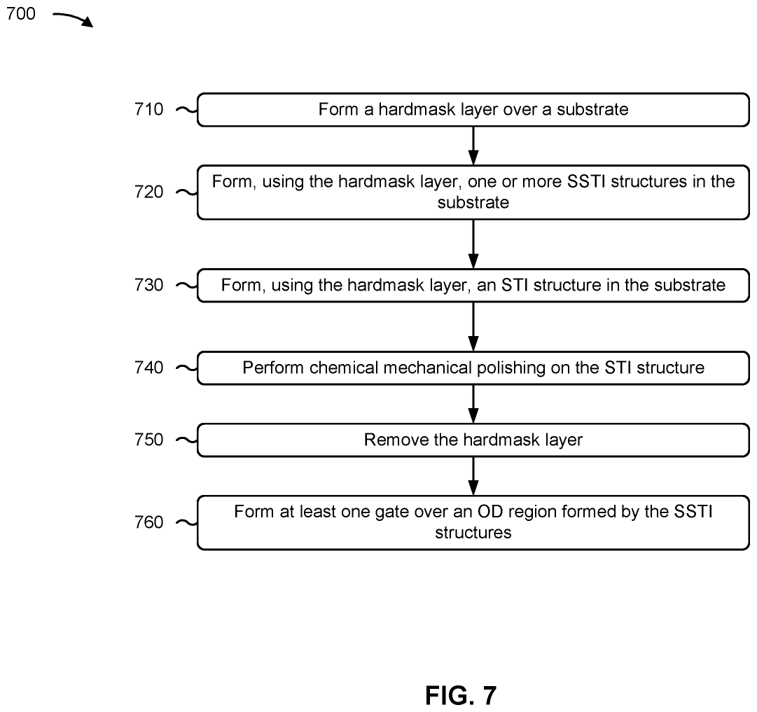

FIG. 7 is a flowchart of an example process 700 associated with forming isolation structures described herein. In some implementations, one or more process blocks of FIG. 7 are performed using one or more semiconductor processing tools (e.g., one or more of the semiconductor processing tools 102-116). Additionally, or alternatively, one or more process blocks of FIG. 7 may be performed using one or more components of device 600, such as processor 620, memory 630, input component 640, output component 650, and/or communication component 660.

As shown in FIG. 7, process 700 may include forming a hardmask layer over a substrate (block 710). For example, one or more of the semiconductor processing tools 102-116 may be used to form a hardmask layer 502 over a substrate 302, as described herein.

As further shown in FIG. 7, process 700 may include forming, using the hardmask layer, one or more SSTI structures in the substrate (block 720). For example, one or more of the semiconductor processing tools 102-116 may be used to form, using the hardmask layer 502, one or more SSTI structures 404 in the substrate 302, as described herein.

As further shown in FIG. 7, process 700 may include forming, using the hardmask layer, an STI structure in the substrate (block 730). For example, one or more of the semiconductor processing tools 102-116 may be used to form, using the hardmask layer 502, an STI structure 202 in the substrate 302, as described herein.

As further shown in FIG. 7, process 700 may include performing chemical mechanical polishing on the STI structure (block 740). For example, one or more of the semiconductor processing tools 102-116 may be used to perform CMP on the STI structure 202, as described herein.

As further shown in FIG. 7, process 700 may include removing the hardmask layer (block 750). For example, one or more of the semiconductor processing tools 102-116 may be used to remove the hardmask layer 502, as described herein.

As further shown in FIG. 7, process 700 may include forming at least one gate over an OD region formed by the SSTI structures (block 760). For example, one or more of the semiconductor processing tools 102-116 may be used to form at least one gate 206 over an OD region formed by the SSTI structures 404, as described herein.

Process 700 may include additional implementations, such as any single implementation or any combination of implementations described below and/or in connection with one or more other processes described elsewhere herein.

In a first implementation, forming the hardmask layer 502 includes forming the hardmask layer 502 with a height in a range from approximately 500 Å to approximately 1000 Å.

In a second implementation, alone or in combination with the first implementation, process 700 includes forming a padding layer 408 between the substrate 302 and the hardmask layer 502. Process 700 may further include removing the padding layer 408 after removing the hardmask layer.

In a third implementation, alone or in combination with one or more of the first and second implementations, forming the one or more SSTI structures 404 includes forming one or more recesses 506 in the substrate 302 and filling the one or more recesses 506 with a dielectric material to form the one or more SSTI structures 404. Forming the one or more SSTI structures 404 may further include forming one or more lining layers 406 in the one or more recesses 506 before filling the one or more recesses 506.

In a fourth implementation, alone or in combination with one or more of the first through third implementations, forming the STI structure 202 includes forming a recess 518 in the substrate 302 and filling the recess 518 with a dielectric material to form the STI structure 202. Forming the STI structure 202 may further include forming a lining layer 402 in the recess 518 before filling the recess 518.

Although FIG. 7 shows example blocks of process 700, in some implementations, process 700 includes additional blocks, fewer blocks, different blocks, or differently arranged blocks than those depicted in FIG. 7. Additionally, or alternatively, two or more of the blocks of process 700 may be performed in parallel.

In this way, using a same hardmask layer during formation of some isolation structures (e.g., SSTI structures) and during formation of additional isolation structures (e.g., STI structures) results in the isolation structures being approximately level with a horizontal surface of a substrate in which the isolation structures are formed. That is, a step height of the isolation structures is reduced. Therefore, heights of portions of gates that extend over the isolation structures are increased. The increased heights of the gates result in increased landing areas for contacts, which helps prevent current leakage and thus improves performance of electronic devices that include the isolation structures.

As described in greater detail above, some implementations described herein provide a semiconductor structure. The semiconductor structure includes a substrate. The semiconductor structure includes a shallow trench isolation (STI) structure formed in the substrate. The semiconductor structure includes a shallower STI (SSTI) structure formed in the substrate and resulting in an oxide definition (OD) region. The semiconductor structure includes a gate formed over the OD region and partially overlapping the STI structure, where the gate has a first height over the STI structure and a second height over the OD region. The first height and the second height are approximately equal.

As described in greater detail above, some implementations described herein provide a method. The method includes forming a hardmask layer over a substrate. The method includes forming, using the hardmask layer, one or more shallower shallow trench isolation (SSTI) structures in the substrate. The method includes forming, using the hardmask layer, a shallow trench isolation (STI) structure in the substrate. The method includes performing chemical mechanical polishing on the STI structure. The method includes removing the hardmask layer. The method includes forming at least one gate over an oxide definition (OD) region formed by the SSTI structures.

As described in greater detail above, some implementations described herein provide a semiconductor structure. The semiconductor structure includes a substrate. The semiconductor structure includes a shallow trench isolation (STI) structure formed in the substrate, where the STI structure has a step height relative to the substrate that is in a range from 0.0 nanometers (nm) to approximately 2.0 nm. The semiconductor structure includes a shallower STI (SSTI) structure formed in the substrate and resulting in an oxide definition (OD) region, where the SSTI structure has a step height relative to the substrate that is in a range from 0.0 nm to approximately 2.0 nm. The semiconductor structure includes a gate formed over the OD region and partially overlapping the STI.

As used herein, “satisfying a threshold” may, depending on the context, refer to a value being greater than the threshold, greater than or equal to the threshold, less than the threshold, less than or equal to the threshold, equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate;
a shallow trench isolation (STI) structure formed in the substrate;
a shallower STI (SSTI) structure formed in the substrate and resulting in an oxide definition (OD) region; and
a gate formed over the OD region and partially overlapping the STI structure,
wherein the gate has a first height over the STI structure and a second height over the OD region, and the first height and the second height are approximately equal.

2. The semiconductor structure of claim 1, further comprising:
a gate contact in physical contact with the gate.

3. The semiconductor structure of claim 1, further comprising:
a source contact physically contacting a source region adjacent to the STI structure.

4. The semiconductor structure of claim 1, further comprising:
a drain contact physically contacting a drain region adjacent to the SSTI structure.

5. The semiconductor structure of claim 1, wherein the STI structure includes a lining layer.

6. The semiconductor structure of claim 1, wherein the substrate includes a laterally diffused metal-oxide-semiconductor (LDMOS).

7. A method, comprising:
forming a hardmask layer over a substrate;
forming, using the hardmask layer, one or more shallower shallow trench isolation (SSTI) structures in the substrate;
forming, using the hardmask layer, a shallow trench isolation (STI) structure in the substrate;
performing chemical mechanical polishing on the STI structure;
removing the hardmask layer; and
forming at least one gate over an oxide definition (OD) region formed by the SSTI structures.

8. The method of claim 7, wherein forming the hardmask layer comprises:
forming the hardmask layer with a height in a range from approximately 500 Ångströms (Å) to approximately 1000 Å.

9. The method of claim 7, further comprising:
forming a padding layer between the substrate and the hardmask layer.

10. The method of claim 9, further comprising:
removing the padding layer after removing the hardmask layer.

11. The method of claim 7, wherein forming the one or more SSTI structures comprises:
forming one or more recesses in the substrate; and
filling the one or more recesses with a dielectric material to form the one or more SSTI structures.

12. The method of claim 11, wherein forming the one or more SSTI structures further comprises:
forming one or more lining layers in the one or more recesses before filling the one or more recesses.

13. The method of claim 7, wherein forming the STI structure comprises:
forming a recess in the substrate; and
filling the recess with a dielectric material to form the STI structure.

14. The method of claim 13, wherein forming the STI structure further comprises:
forming a lining layer in the recess before filling the recess.

15. A semiconductor structure, comprising:
a substrate;
a shallow trench isolation (STI) structure formed in the substrate,
wherein the STI structure has a step height relative to the substrate that is in a range from 0.0 nanometers (nm) to approximately 2.0 nm;
a shallower STI (SSTI) structure formed in the substrate and resulting in an oxide definition (OD) region,
wherein the SSTI structure has a step height relative to the substrate that is in a range from 0.0 nm to approximately 2.0 nm; and
a gate formed over the OD region and partially overlapping the STI structure.

16. The semiconductor structure of claim 15, further comprising:
a gate contact physically contacting the gate; and
a dielectric layer surrounding the gate contact.

17. The semiconductor structure of claim 16, wherein the dielectric layer is formed of a same material as the STI structure.

18. The semiconductor structure of claim 15, wherein the SSTI structure includes a lining layer.

19. The semiconductor structure of claim 15, wherein the gate has a first height over the STI structure and a second height over the OD region, and the first height and the second height are approximately equal.

20. The semiconductor structure of claim 15, wherein the substrate includes a laterally diffused metal-oxide-semiconductor (LDMOS).
